(19) United States
(12) Patent Application Publication
(10) Pub. No.: US 2024/0235701 A1
(43) Pub. Date: Jul. 11, 2024

(54) POWER AMPLIFIER CALIBRATION SYSTEM AND METHOD

(71) Applicant: Qorvo US, Inc., Greensboro, NC (US)

(72) Inventor: Masashi Nogawa, Sachse, TX (US)

(21) Appl. No.: 18/382,800

(22) Filed: Oct. 23, 2023

Related U.S. Application Data
(60) Provisional application No. 63/479,427, filed on Jan. 11, 2023.

(51) Int. Cl. H04B 17/13; G01S 13/88; H03F 3/189; H03F 3/21

(52) U.S. Cl. CPC H04B 17/13; G01S 13/88; H03F 3/189; H03F 3/21; H03F 2200/451

(57) ABSTRACT

Power amplifier calibration systems and methods are disclosed. In one aspect, the method is well-suited for use in calibrating a high-power amplifier such as might be used in a radar installation. The method warms up the power amplifier by sending a realistic signal, including dummy pulses to the power amplifier for a period of time until the power amplifier reaches an approximate steady state of operation. A calibration tool then sweeps a voltage level at a gate of the power amplifier through a range of voltages until a desired drain current is measured. The voltage corresponding to the desired drain current is then used as a bias voltage for future operation. By allowing the power amplifier to reach the steady state, transient responses that may occur at a cold start are avoided and a proper bias signal determined.

### PRIORITY APPLICATIONS

The present application is related to U.S. Provisional Patent Application Ser. No. 63/479,427 filed on Jan. 11, 2023, and entitled “POWER AMPLIFIER CALIBRATION SYSTEM AND METHOD,” the contents of which are incorporated herein by reference in its entirety.

### BACKGROUND

### I. Field of the Disclosure

The technology of the disclosure relates generally to power amplifiers and, more particularly, to techniques to calibrate bias voltages for power amplifiers.

### II. Background

Wireless communication relies on wireless transmitters and wireless receivers. In almost any implementation of a wireless transmitter, there is some form of power amplifier that boosts a signal to a desired level before providing the signal to an antenna for transmission. Some communication adjacent technologies, such as radar systems, also rely on wireless transmitters with power amplifiers used to boost a signal to a desired level. In most cases, power amplifiers receive a direct current bias signal to assist in forcing operation of the power amplifier in a desired class (e.g., A, B, AB, etc.). Calibrating the bias signal correctly provides room for innovation.

### SUMMARY

Aspects disclosed in the detailed description include a power amplifier calibration system and method. In an exemplary aspect, the method is well-suited for use in calibrating a high-power amplifier such as might be used in a radar installation. The method warms up the power amplifier by sending a realistic signal, including dummy pulses, to the power amplifier for a period of time until the power amplifier reaches an approximate steady state of operation. A calibration tool then sweeps a voltage level at a gate of the power amplifier through a range of voltages until a desired drain current is measured. The voltage corresponding to the desired drain current is then used as a bias voltage for future operation. By allowing the power amplifier to reach the steady state, transient responses that may occur at a cold start are avoided, and a proper bias signal is determined.

In this regard, in one aspect, a power amplifier calibration process is disclosed. The process comprises warming up a power amplifier through a plurality of dummy pulses. The process also comprises, after warming up the power amplifier, sweeping through a plurality of gate voltages until a desired drain current is detected.

In another aspect, a calibration system is disclosed. The calibration system comprises a device under test comprising a power amplifier. The calibration system also comprises a radio frequency (RF) signal generator circuit coupled to an RF input of the power amplifier. The calibration system also comprises a current sensor coupled to a drain of the power amplifier. The calibration system also comprises a controller. The controller is configured to receive a detection signal from the current sensor. The controller is also configured to sweep a gate voltage source through a plurality of values to change current at the current sensor. The controller is also configured to interrupt delivery of an RF signal to the power amplifier during the sweep. The controller is also configured to warm up the power amplifier through delivery of a series of dummy pulses to the power amplifier.

### BRIEF DESCRIPTION OF THE DRAWINGS

FIG. 1 is a block diagram of an exemplary radar system having a power amplifier having a bias signal that may need calibration;

FIG. 2A is a circuit diagram of a power amplifier such as may be used in the radar system of FIG. 1 that uses drain switching for the bias signal;

FIG. 2B is a circuit diagram of a power amplifier such as may be used in the radar system of FIG. 1 that uses gate switching for the bias signal;

FIG. 3 is a flowchart illustrating a conventional calibration process;

FIG. 4A is a hybrid circuit and block diagram of the power amplifier of FIG. 2A connected to a calibration circuit;

FIG. 4B is a timing diagram of gate voltage and drain current during the calibration of the power amplifier in the system of FIG. 4A;

FIG. 5 is a flowchart illustrating a calibration process according to exemplary aspects of the present disclosure;

FIG. 6 is a hybrid circuit and block diagram of a power amplifier connected to a calibration circuit according to exemplary aspects of the present disclosure where a dummy pulse is generated by stopping a radio frequency (RF) signal generator circuit; and

FIG. 7 is a hybrid circuit and block diagram of a power amplifier connected to a calibration circuit according to exemplary aspects of the present disclosure, where a dummy pulse is generated by blocking an RF signal generator circuit.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a power amplifier calibration system and method. In an exemplary aspect, the method is well-suited for use in calibrating a high-power amplifier such as might be used in a radar installation. The method warms up the power amplifier by sending a realistic signal, including dummy pulses, to the power amplifier for a period of time until the power amplifier reaches an approximate steady state of operation. A calibration tool then sweeps a voltage level at a gate of the power amplifier through a range of voltages until a desired drain current is measured. The voltage corresponding to the desired drain current is then used as a bias voltage for future operation. By allowing the power amplifier to reach the steady state, transient responses that may occur at a cold start are avoided, and a proper bias signal is determined.

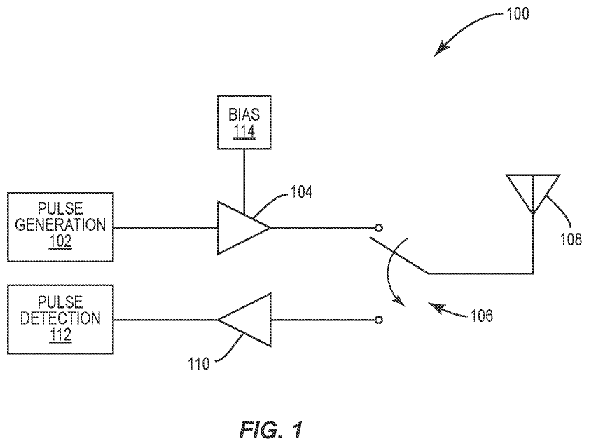

In this regard, FIG. 1 is a simplified block diagram of a radar system 100. The radar system 100 may have a pulse generation circuit 102 that generates a pulse to be transmitted at an appropriate radio frequency (RF). This RF pulse is amplified by a power amplifier 104 and passed through a switch 106 to an antenna 108. The antenna 108 emits the pulse out into the surrounding environment. When the pulse hits an object, a reflection is generated. This reflection travels back to the antenna 108 through the switch 106 to a receive amplifier 110, which may be a low noise amplifier (LNA) or the like. The amplified received signal is then passed to a pulse detection circuit 112 which discerns that the received signal is a reflection and not just random noise. The pulse detection circuit 112 may use time delay and/or amplitude information to determine a distance from the antenna 108 to the object that generated the reflection. A bias circuit 114 provides a bias voltage to the power amplifier 104.

In a typical radar system, it is generally desirable that the power amplifier 104 operate as a class AB device and accordingly, the bias provided by the bias circuit 114 should be sufficient to keep the power amplifier 104 in the class AB operating range. This desire to have a specific operating range for the power amplifier 104 leads to calibrating the bias circuit 114 so that a desired bias signal is provided.

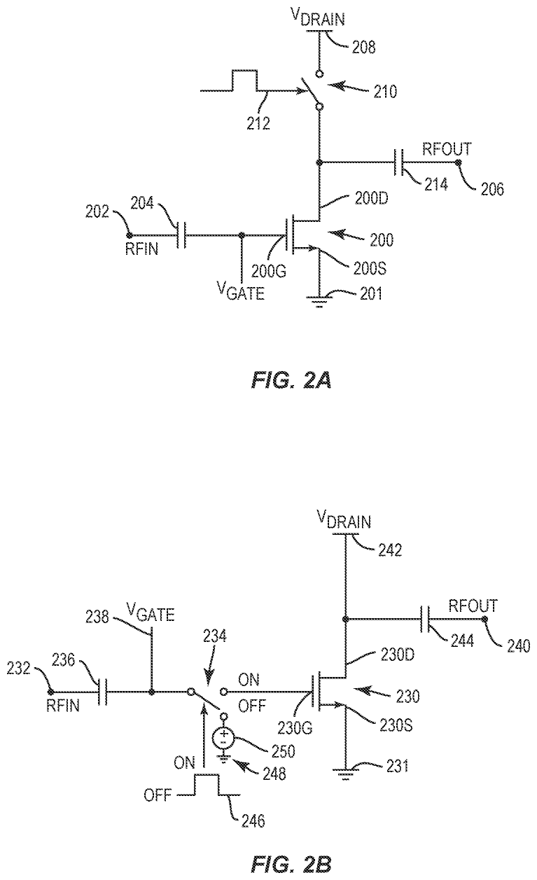

The bias signal from the bias circuit 114 may be provided in one of at least two ways. More specifically, the bias signal may be provided through drain switching or gate switching as shown in FIGS. 2A and 2B, respectively. In this regard, FIG. 2A illustrates a power amplifier 200, analogous to the power amplifier 104. The power amplifier 200 may be a field-effect transistor (FET) having a gate 200G, a drain 200D, and a source 200S. The source 200S is coupled to a ground 201. The gate 200G is coupled to an RF input 202. There may be a capacitor 204 to block direct current (DC) or low frequency signals. The drain 200D is coupled to an RF output 206 and a drain voltage source 208 (also referred to as Vdrain in FIG. 2A). A switch 210 may be serially positioned between the RF output 206 and the drain voltage source 208. A low-frequency signal 212 may open and close the switch 210, throttling the voltage provided as a bias signal to the power amplifier 200. A capacitor 214 may block DC signals from passing to the RF output 206. The duty cycle of the signal 212 controls how much time the drain voltage source 208 is coupled to the drain 200D, which in turn controls the voltage level at the RF output 206.

FIG. 2B shows a similar power amplifier 230 with a gate 230G, a drain 230D, and a source 230S. The source 230S is coupled to a ground 231. The gate 230G is coupled to an RF input 232 through a switch 234 and a capacitor 236. A voltage source 238 (also referred to as Vgate in FIG. 2B) is coupled to the switch 234. The drain 230D is coupled to an RF output 240 and a voltage source 242 (Vdrain). A capacitor 244 may block DC signals from passing to the RF output 240. A low frequency signal 246 may toggle the switch 234 between a ground 248 and the gate 230G. Note that in a gallium nitride (GaN) device, a strong negative voltage source 250 (e.g., −5 volts) may be positioned between the switch 234 and the ground 248 to turn off the gate switching since GaN transistors are normally-ON devices. For example, when the signal 246 is at a logical low (or OFF), the switch 234 may be coupled to ground 248 through the voltage source 250, and when the signal 246 is at a logical high (or ON), the switch may couple Vgate to the gate 230G. Toggling the switch 234 in this fashion throttles the input signal and the bias provided by the voltage source 238. Again, the duty cycle of the signal 246 controls how much time the voltage source 238 is coupled to the gate 230G, which in turn controls how often the power amplifier 230 is on.

While aspects of the present disclosure may be applied to both forms of biasing, the present disclosure will focus on the drain switching of FIG. 2A.

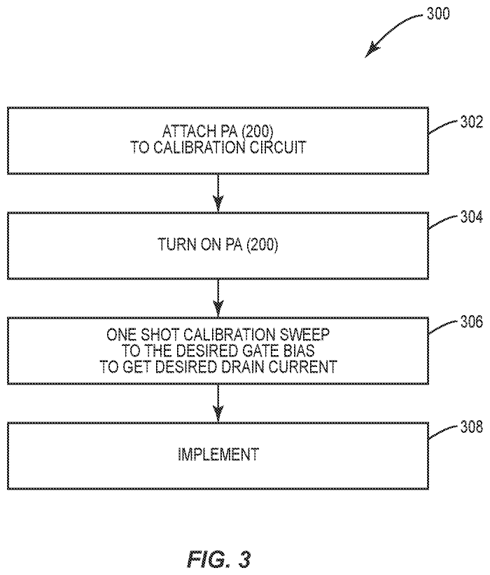

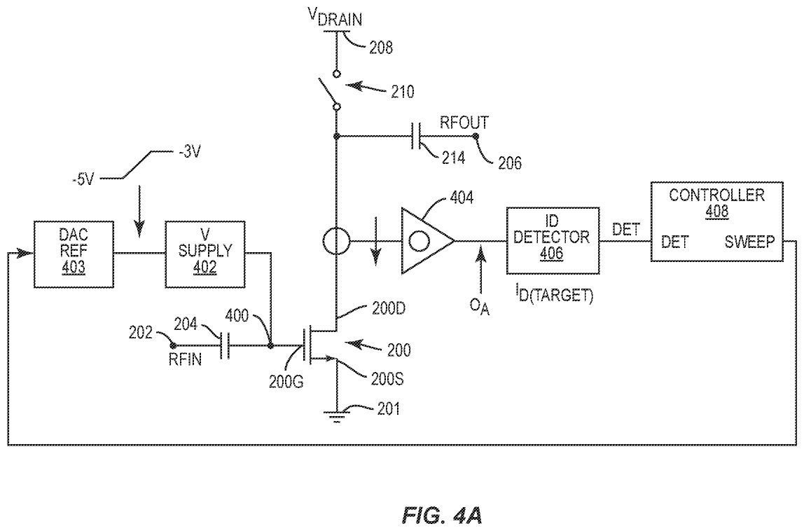

In the past, the bias signal might be calculated as shown by process 300 in FIG. 3. Specifically, the power amplifier 200 is attached to a calibration circuit (block 302). This may be done through a probe, a built-in test circuit, or the like. The power amplifier 200 is turned on (block 304). The calibration circuit sweeps in one shot through a range of voltages to find a desired gate bias to get a desired drain current (block 306). This value may be stored and the power amplifier 200 with an appropriate bias may be implemented (block 308) such as through installation into a radar system 100.

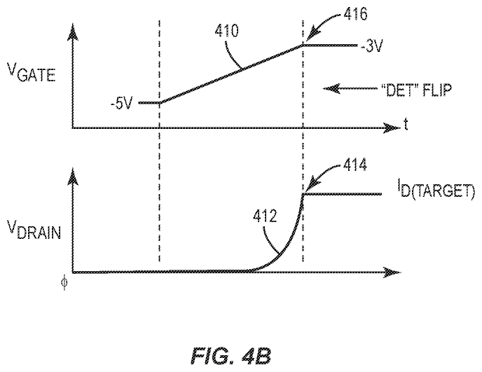

FIG. 4A provides a hybrid block and circuit diagram of a calibration circuit coupled to a power amplifier 200 to implement the process 300. Specifically, for purposes of example, the power amplifier 200 is under test although the power amplifier 230 could also be used. A probe 400 may be coupled to the gate 200G and provide a voltage signal from a gate voltage source 402. This voltage signal will turn on the power amplifier 200 and current will flow from the drain 200D to the source 200S. The gate voltage source 402 may be controlled by a digital-to-analog converter (DAC) 403, which sweeps through a range of voltage values (e.g., −5 volts (V) to −3 V), which causes different drain currents to be generated. These drain currents may be sensed by a current sensor 404 and a current detector 406. When the drain current hits the target, a detection (DET) signal may be sent from the current detector 406 to a controller 408. The controller 408 also provides a sweep signal to the DAC 403, causing the DAC 403 to change values and thus make the sweep. During the process 300, the switch 210 may be closed, coupling the drain voltage source 208 to the power amplifier 200.

In practice, the voltage signal generated by the gate voltage source 402 is shown by voltage line 410 in FIG. 4B. At some point, the voltage will cause the drain current 412 to hit the target 414. This value 416 may be used to set the bias signal.

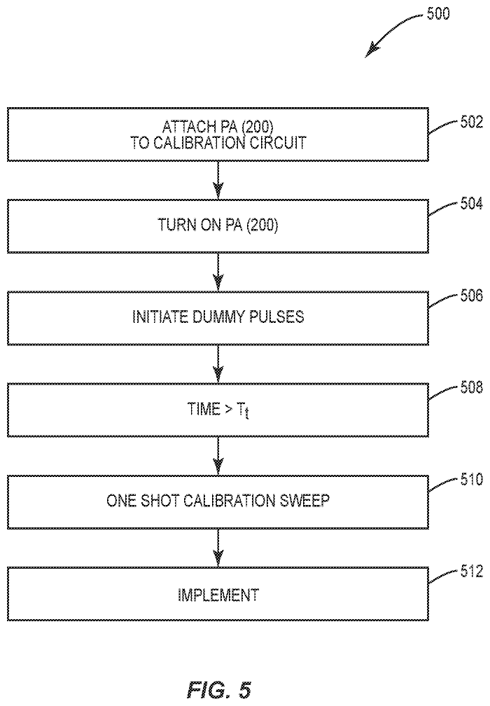

It has been observed that the process 300 may lead to use of bias points that do not align with desired drain currents when used in a radar system. Realizing that the cold start nature of the testing and calibration in the process 300 was different from how radar systems work in normal operation, exemplary aspects of the present disclosure provide an alternate process 500, illustrated in FIG. 5 that more accurately simulates normal operation and provides for a more accurate bias calibration.

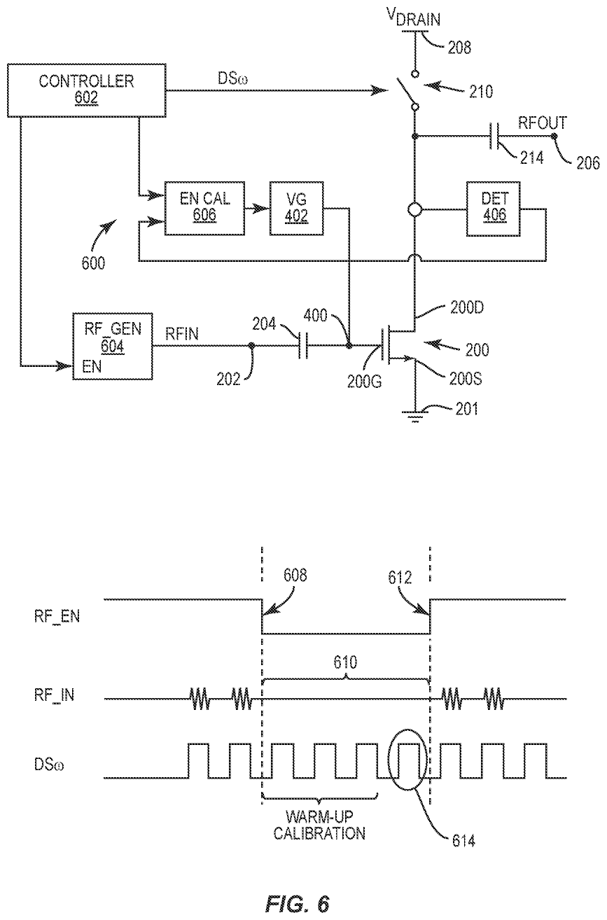

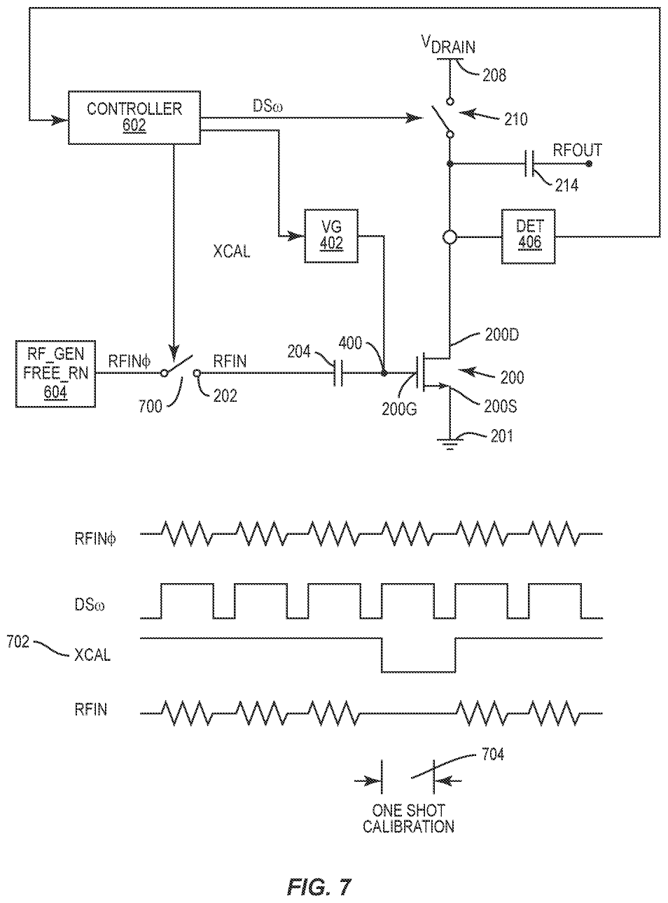

In this regard, the process 500 begins by attaching a power amplifier 200 to a calibration circuit (block 502). The power amplifier 200 is turned on (block 504). A controller of the calibration circuit initiates a series of dummy pulses (block 506). In an exemplary aspect, the dummy pulses are generated in a window where there is no RF signal at the RF input 202, and thus, there is no signal being amplified by the power amplifier 200. There are at least two ways to achieve this isolation between the RF input 202 and the power amplifier 200 as better illustrated with reference to FIGS. 6 and 7 below. Likewise, there are at least two ways to form the dummy pulses as also explained with reference to FIGS. 6 and 7.

The controller determines if the dummy pulses have been generated for a time greater than a threshold time (Tt) (block 508) where the threshold time is chosen so as to give the system time to settle. Once the system has settled (i.e., the power amplifier 200 is warmed up in a manner similar to normal operation), the controller may initiate a one-shot calibration sweep (block 510, but similar to block 306). Once the drain current reaches a desired value, the calibration is complete and may be discontinued while the power amplifier is implemented into the end device (block 512).

FIG. 6 provides a hybrid circuit and block diagram of a calibration circuit 600 coupled to the power amplifier 200 that allows the normal RF input signal to be suspended while calibration occurs. Many of the elements of the calibration circuit 600 are identical to the structure disclosed above. However, the calibration circuit 600 includes a controller 602 (also sometimes referred to as a control circuit) that generates an RF enable (RF_EN) signal to control the signal at the RF input 202. Specifically, when the RF_EN signal is active, a normal RF signal is provided by an RF signal generator circuit 604 (analogous to the pulse generation circuit 102 of FIG. 1). When the RF_EN signal is inactive, the RF signal generator circuit 604 does not generate any signal for the RF input 202.

The controller 602 controls the gate voltage source 402 through a calibration enable circuit 606 and uses the gate voltage source 402 to sweep through the voltages to find the desired drain current with the current detector 406. The current detector 406 also provides a signal to the calibration enable circuit 606 (or the controller 602 if desired), where this signal is indicative of the drain current.

The controller 602 also controls the switch 210 through a dummy signal (DSω). In particular, the controller 602 may turn off the RF signal generator circuit 604 with a logical low on the RF_EN signal (shown at 608). This causes RF_IN to also stop having pulses (shown at window 610). Meanwhile, DSω toggles the switch 210 to warm up the power amplifier 200 using pulses from the voltage source 208, and before RF_EN is toggled back to a logical high at 612, the calibration sweep is done (shown at 614).

An alternate aspect is shown in FIG. 7 where instead of turning off the RF signal entirely by turning off the RF signal generator circuit 604, a switch 700 is opened during the calibration process such that the RFinϕ does not reach the power amplifier 200. The switch 700 is controlled by an XCAL signal 702, and the voltage sweep is done in window 704. This arrangement allows the use of the RF signal RF_IN to warm up the power amplifier 200 using a plurality of preliminary RF signal pulses and may eliminate the need for the artificial dummy pulse used in FIG. 6. As used herein, the RF signal is, during this warm-up phase, considered the dummy pulse.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power amplifier calibration process comprising:
warming up a power amplifier through a plurality of dummy pulses; and
after warming up the power amplifier, sweeping through a plurality of gate voltages until a desired drain current is detected.

2. The power amplifier calibration process of claim 1, wherein warming up the power amplifier through the plurality of dummy pulses comprises turning off a radio frequency (RF) signal generator circuit and toggling a drain voltage source periodically.

3. The power amplifier calibration process of claim 1, wherein warming up the power amplifier through the plurality of dummy pulses comprises using a radio frequency (RF) signal generator circuit to generate a plurality of preliminary RF signal pulses.

4. The power amplifier calibration process of claim 3, further comprising isolating the RF signal generator circuit from the power amplifier during the sweeping by opening a switch.

5. The power amplifier calibration process of claim 2, wherein toggling the drain voltage source periodically comprises opening and closing a switch.

6. The power amplifier calibration process of claim 1, further comprising storing information relating to a gate voltage that gives the desired drain current for subsequent use.

7. The power amplifier calibration process of claim 1, wherein the plurality of dummy pulses mimic radar system pulses.

8. The power amplifier calibration process of claim 1, further comprising implementing the power amplifier in a radar system.

9. A calibration system comprising:
a device under test comprising a power amplifier;
a radio frequency (RF) signal generator circuit coupled to an RF input of the power amplifier;
a current sensor coupled to a drain of the power amplifier; and
a controller configured to:
receive a detection signal from the current sensor;
sweep a gate voltage source through a plurality of values to change current at the current sensor;
interrupt delivery of an RF signal to the power amplifier during the sweep; and
warm up the power amplifier through delivery of a series of dummy pulses to the power amplifier.

10. The calibration system of claim 9, wherein the controller is further configured to open a switch between the RF signal generator circuit and the power amplifier.

11. The calibration system of claim 9, wherein the controller is further configured to send a dummy signal to a switch between a drain voltage source and the power amplifier.

12. The calibration system of claim 9, wherein a signal from the RF signal generator circuit provides the series of dummy pulses.
